(19) United States
(12) Patent Application Publication
(10) Pub. No.: US 2024/0413139 A1
(43) Pub. Date: Dec. 12, 2024

(54) Apparatus and Methods of Manufacturing a Apparatus and Methods of Manufacturing a Combined 2D/3D Led Display System

(71) Applicant: Liminal Space, Inc., Los Angeles, CA (US)

(72) Inventor: Nathaniel Huber, Hollywood, CA (US)

(21) Appl. No.: 18/208,216

(22) Filed: Jun. 9, 2023

(51) Int. Cl. H01L 25/13; G02B 30/25

(52) U.S. Cl. CPC H01L 25/13; G02B 30/25

(57) ABSTRACT

The present invention provides systems, and methods for manufacturing an array of multiple polarizing light emitting packages (MLEPs), wherein each of MLEPs includes a first left sector, a second left sector, a first right sector, and a second right sector; and each sector of the MLEPs includes at least a first light emitting element and a polarizer; and the MLEPs are positioned and oriented within the array such that when the array is viewed through glasses with corresponding polarizing lenses, a viewer perceives an image displayed by the array as a three-dimensional image. Each sector of the MLEPs is separated by a distance, and each polarizer is separated from others via an opaque, separator wall.

### FIELD OF THE INVENTION

The present invention generally relates to stereoscopic display systems.

### BACKGROUND

Stereoscopic display systems attempt to recreate a real world visual experience wherein a viewer sees a different view or image in each eye. In a real world viewing experience, a viewer with two eyes sees two slightly different images, as each eye is spaced apart in a slightly different viewing position. A goal of stereoscopic video display systems is to present a separate and different view to each eye of the viewer.

Earlier attempts to recreate a real world visual 3D experience employed an apparatus similar to corrective eyewear comprised of one lens of one color and second lens of a second color. A monitor or projector projected two views on one screen, with each view being color coded so as to be complementary to one eyewear lens or the other. The use of color to segregate viewing channels would often lead to headaches for the viewers.

Recent 3D designs focus on creating a 3D viewing experience within a traditional movie theater environment, using devices centering around a display on a lenticular screen constructed of fabric. However, limited stereoscopic viewing advancements have occurred outside the movie theater environment, including on billboards and other public media/advertising delivery devices. U.S. Pat. No. 10,298,919 to Li teaches a “polarizing stereo electronic large screen display system” with “ . . . two individual pixels [,] each including three primary colors inside one physical pixel for respectively emitting light for the left eye and the right eye”. (Li, Abstract). Indeed, Li's “display pixels” refer to “physical pixel [s], [where] each display pixel includes two individual electronic pixels, i.e. inserting two individual electronic pixels within each display pixel”. (Li, col. 4, ln. 19-22). The LED's described by Li require two pixels to be processed and displayed, while some standard single LED arrangements would only produce one pixel. That is, Li's system requires custom controllers to process received image content, custom content processing devices, and custom LEDs that process two pixels at once. In general, it would be desirable to provide a 3D viewing experience using a wider range of devices, billboards, LED movie theater screens, stadium jumbotrons, and/or other large display devices. Accordingly, although great strides have been made in the area of stereoscopic display systems, many shortcomings remain.

### SUMMARY OF THE INVENTION

According to one aspect of the present design, there is provided a stereoscopic display system, comprising: an array of multiple polarizing light emitting packages (MLEPs), wherein: each of MLEPs includes a first left sector, a second left sector, a first right sector, and a second right sector; and, each sector of the MLEPs includes at least a first light emitting element and a polarizer; and, the MLEPs are positioned and oriented within the array such that when the array is viewed through glasses with corresponding polarizing lenses, a viewer perceives an image displayed by the array as a three-dimensional image.

According to another embodiment of the present design, there is provided a method of manufacturing a stereoscopic display system having an array of multiple polarizing light emitting packages (MLEPs), comprising providing within each of MLEPs, a first left sector, a second left sector, a first right sector, and a second right sector; providing within each sector of the MLEPs, at least a first light emitting element and a polarizer; and, positioning the MLEPs within the array such that when the array is viewed through glasses with corresponding polarizing lenses, a viewer perceives an image displayed by the array as a three-dimensional image.

In another embodiment of the inventive concept, we propose a system that has a single pixel being represented by the LED, while the system maintains the standard 2D function of an LED when 2D content is displayed. In another embodiment of the present design, the described MLEPs advantageously remove the need for a special controller processing two pixels in a single LED space, such that the MLEPs would be configured for a similar form factor and functionality as a normal 2D LED, with similar image control devices as a standard 2D LED, but when 3D content is played through the MLEPs, the user would be able to see a 3D image.

These and other advantages of the present invention will become apparent to those skilled in the art from the following detailed description of the invention and the accompanying drawings.

Various resources, features, aspects and advantages of the inventive subject matter will become more apparent from the following detailed description of preferred embodiments, along with the accompanying drawing figures in which like numerals represent like components.

### BRIEF DESCRIPTION OF THE DRAWINGS

FIG. 1A is a top left perspective view of an multiple polarizing light emitting packages (MLEPS) assembly, each with a polarizer and disposed in their own sector.

FIG. 1B is a top left perspective view of an alternative embodiment of the multiple polarizing light emitting packages (MLEPS) assembly, each with multiple light emitting elements, a polarizing element, and disposed in their own sector.

FIG. 1C is a reverse perspective view of FIG. 1A with multiple polarizing light emitting packages (MLEPS) assembly, each with a polarizing element and disposed in their own sector.

FIG. 2A is a top left perspective view of an alternative MLEPS assembly, with diagonally oriented sectors.

FIG. 2B is a reverse perspective view of the alternative MLEPS assembly in FIG. 2A, with diagonally oriented sectors.

FIG. 3A is a top left perspective view of another alternative MLEPS assembly, with separators between the sectors.

FIG. 3B is a top left perspective view of another alternative MLEPS assembly, with multiple light emitting elements and separators between the sectors.

FIG. 3C illustrates a front perspective view of an alternative embodiment similar to FIG. 3B.

FIG. 4 is a flowchart of one embodiment of a method of manufacturing a stereoscopic display system having an array of MLEPS.

### DETAILED DESCRIPTION

The following discussion provides many example embodiments of the inventive subject matter. Although each embodiment represents a single combination of inventive elements, the inventive subject matter is considered to include all possible combinations of the disclosed elements. Thus, if one embodiment comprises elements A, B, and C, and a second embodiment comprises elements B and D, then the inventive subject matter is also considered to include other remaining combinations of A, B, C, or D, even if not explicitly disclosed.

The present design is useful in overcoming issues with previous designs by providing a method of manufacturing multiple polarizing light emitting packages (MLEPs), wherein each MLEP includes a plurality of sectors, and each sector of the includes a light emitting element and a polarizer, such that the MLEPs are positioned and oriented within the array to display a 2D/3D image or similar video content. It is to be understood that any type of semiconductor package (or “SP”) may be employed in the current design. While the present description generally SP's using RGB (red, green, and blue) semiconductors, it is to be understood the invention is not so limited. Any type of semiconductors or similar devices may be employed, including but not limited to RGBY, RGBW (white), RGB plus infrared, OLED, digital RGB, and quantum dot LEDs. In general, the present design relates to the encapsulation of semiconductor packages for stereoscopic viewing.

The applications for this design are therefore numerous and enable realistic 3D viewing at both outdoor and indoor events such as theaters, movie theaters, concerts, and sporting events or anywhere viewers have appropriate eyewear available for 3D viewing. The embodiments are configured to facilitate permanent 3D encapsulated semiconductor package tile or panel manufacturing. The multiple polarizing light emitting packages (MLEPs) when combined into a large display can be used as a standard 2D display by providing 2D video or image content, or the display can show 3D content when playing corresponding stereoscopic 3D video or still images with the appropriate eyewear. Larger display areas (e.g. stadium screens) may beneficially use the teachings herein to provide stereoscopic content.

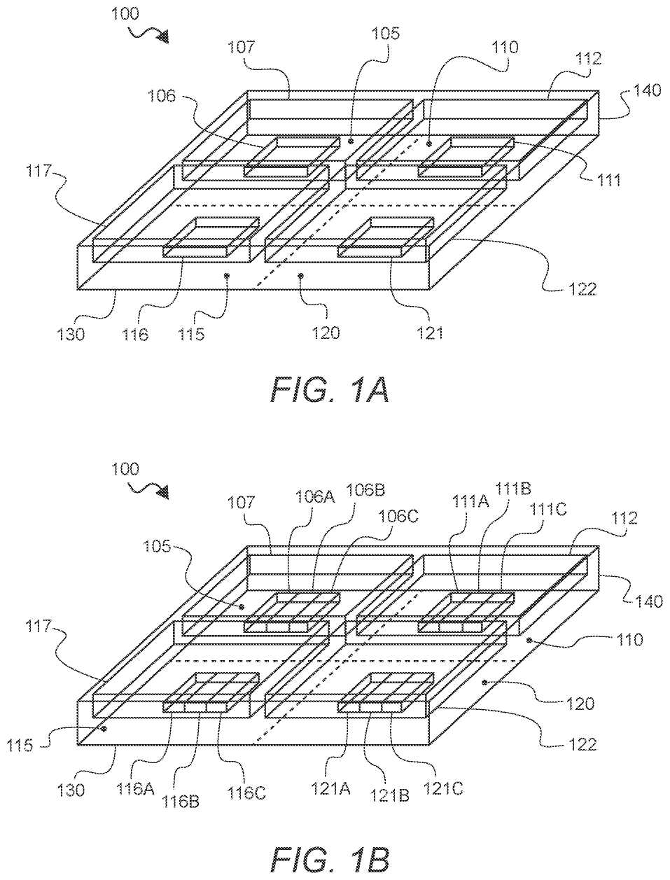

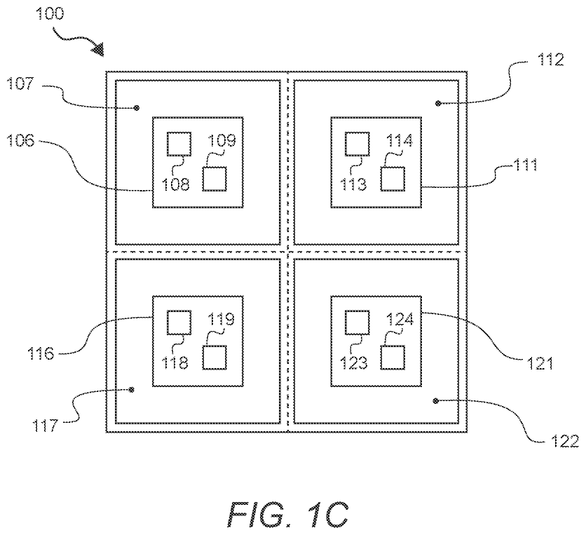

FIG. 1A is a front perspective view of an multiple polarizing light emitting package (MLEP) assembly 100 mounted on a substrate 130 with an assembly wall 140. Each MLEP is disposed in a sector within assembly 100. Sector 105 includes polarizing element 107, where light emitting element 106 disposed below polarizing element 107. Sector 110 includes polarizing element 112, where light emitting element 111 disposed below polarizing element 112. Sector 115 includes polarizing element 117, where light emitting element 116 disposed below polarizing element 117. Sector 120 includes polarizing element 122, where light emitting element 121 disposed below polarizing element 122. In the depicted embodiment, the height of assembly wall 140 is configured to extend a distance above the polarizers of each sector. Advantageously, having the polarizer elements of assembly 100 disposed below a wall edge of assembly wall 140 reduces a possible cross-talk effect, where non-polarized light can escape the light emitting element and affect image quality. In a preferred embodiment, assembly wall 140 is configured to be opaque to visible light.

FIG. 1B is similar to FIG. 1A, except with multiple light emitting elements disposed below the polarizing elements. Sector 105 includes light emitting element 106A, light emitting element 106B, and light emitting element 106C, where the light emitting elements 106A-106C are disposed below polarizing element 107. Sector 110 includes light emitting element 111A, light emitting element 111B, and light emitting element 111C, where the light emitting elements 111A-111C are disposed below polarizing element 112. Sector 115 includes light emitting element 116A, light emitting element 116B, and light emitting element 116C, where the light emitting elements 116A-116C are disposed below polarizing element 117. Sector 120 includes light emitting element 121A, light emitting element 121B, and light emitting element 121C, where the light emitting elements 121A-121C are disposed below polarizing element 122. In some embodiments, the polarizing elements of assembly 100 include a preservation compound (not shown) disposed on an exposed surface of the polarizing elements to protect the surfaces from damage. In a preferred embodiment, the preservation compound has no effect on polarizing light emitted by the light emitting elements of assembly 100. In some embodiments, the preservation compound (not shown) is a resin. In other embodiments, the preservation compound is a glass material.

FIG. 1C is a reverse perspective view of the assembly 100 mounted on a substrate 130. Each light emitting element disposed in a sector also includes an anode and cathode. Light emitting element 105 disposed in a sector includes anode 108 and cathode 109, light emitting element 111 includes anode 113 and cathode 114, light emitting element 116 includes anode 118 and cathode 119, light emitting element 121 includes anode 123 and cathode 124. In a preferred embodiment, each light emitting element produces a color independent of the other light emitting elements within the MLEP assembly 100 via a signal received via its anode and cathode. In other embodiments, sector 105 can include a second light emitting element (not shown) to produce a separate color from light emitting element 106. In related embodiments, the assembly 100 includes a central cathode, with each light emitting element having its own individual anode.

In some embodiments, polarizing elements may be lightly sanded on the bottom facing surface (light emitting element facing side) for a better adhesion to the light emitting element. A polarizing element can be a flexible or inflexible. In some embodiments, an inflexible polarizing element could be made of acrylic or glass. Advantageously, an inflexible polarizing element would be more durable, and provide functionality for a longer period of time. For example, an inflexible polarizing element could be utilized in the manufacture of a permanent outdoor display where the display would be exposed to a variety of weather conditions. In other embodiments, a flexible polarizing element could be made of film, or other light segregating material. Advantageously, a flexible polarizing element could be applied to uneven or irregular surfaces. For example, a flexible polarizing element could be installed above an irregularly shaped or otherwise damaged light emitting element.

In the depicted embodiment, the first light emitting element is configured to emit a first color and a different second color. In a related embodiment, the first light emitting element is configured to additionally emit a third color different from the first and second colors. In an alternative embodiment, each sector of the MLEPs further comprise a second light emitting element configured to emit at least one of the first color and the second color. Light emitting elements can be semiconductors. Each semiconductor may be configured to emit a red, green, or blue light.

In a preferred embodiments, the Sector 105 is separated from Sector 110 by a first distance, the Sector 115 is separated from Sector 120 by a second distance, and the Sector 105 is separated from the Sector 120 by a third distance. In a some embodiments, the first distance is the same as the second distance. In related embodiments, the second distance is the same as the third distance.

It is further contemplated that at least 100 of the MLEPS can be arranged across at least 10 rows. In a similar embodiment, at least 100 of the MLEPS can be arranged across at least 10 diagonals. In a preferred embodiment, at least one of the MLEPs has a visually distinguishable feature selected from the group consisting of a key mark, a slot, and a cut-out.

With respect to use of LEDs generally in stereoscopic image projection, Applicant references the design presented in U.S. Pat. No. 8,542,270 the entirety of which is incorporated herein by reference.

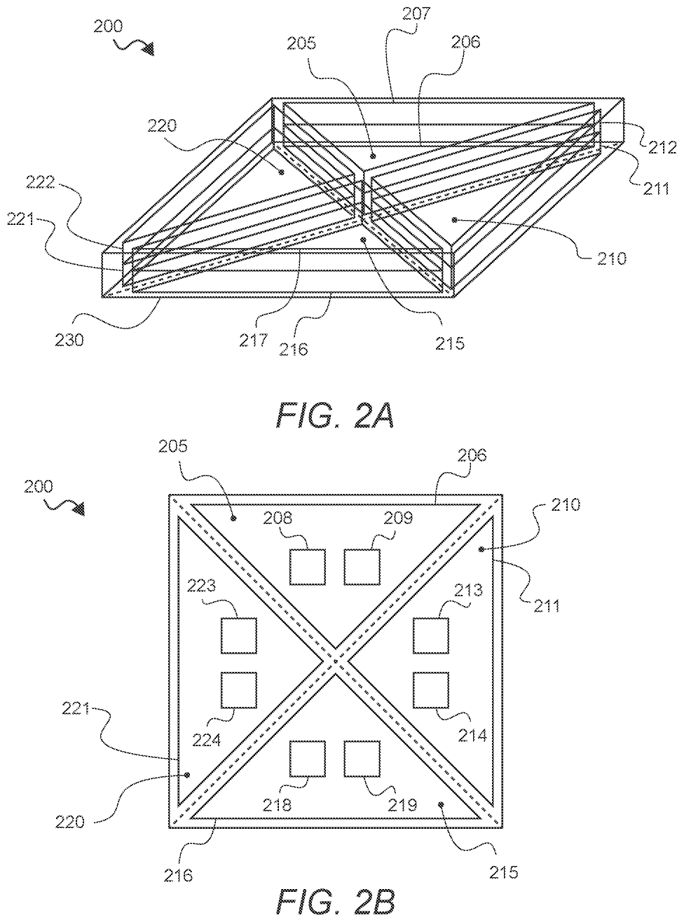

FIG. 2A is a front perspective view of a MLEPS assembly similar to FIG. 1, except with diagonally oriented sectors and an alternative arrangement of polarizers mounted on the substrate. Each MLEP is disposed in a sector within assembly 230. Sector 205 includes polarizing element 207, where light emitting element 206 disposed below polarizing element 207. Sector 210 includes polarizing element 211, where light emitting element 212 disposed below polarizing element 211. Sector 215 includes polarizing element 217, where light emitting element 216 disposed below polarizing element 217. Sector 220 includes polarizing element 222, where light emitting element 221 disposed below polarizing element 222.

Polarizing elements can be substantially fixed in place with bonding solutions. Additionally, bonding solutions can be reactive or non-reactive. In some embodiments, a reactive bonding solution could be glue, epoxy resin, or silicone. In other embodiments, a non-reactive bonding solution could be an acrylic polymer. As used herein, bonding solutions, or any derivative thereof, can refer to any one or more of a reactive bonding solution, non-reactive bonding solution, or combination of reactive and non-reactive bonding solutions. Bonding solutions are cured by the application of an energy. In a preferred embodiment, the bonding solution may be provided between the light emitting element and the polarizing element to ensure that the polarizing element is secured to the light emitting element. In an alternative embodiment, the bonding solution may be applied at edges of the components shown, such as edges of the polarizing element to reduce risk of obscuring or impeding transmission from the light emitting elements.

FIG. 2B is a reverse perspective view of the assembly 200 mounted on a substrate 230. Each light emitting element disposed in a sector also includes an anode and cathode. Light emitting element 205 disposed in a sector includes anode 208 and cathode 209, light emitting element 211 includes anode 213 and cathode 214, light emitting element 216 includes anode 218 and cathode 219, light emitting element 221 includes anode 223 and cathode 224. In a preferred embodiment, each light emitting element produces a color independent of the other light emitting elements within the MLEP assembly 200 via a signal received via its anode and cathode. In other embodiments, sector 205 can include a second light emitting element (not shown) to produce a separate color from light emitting element 206.

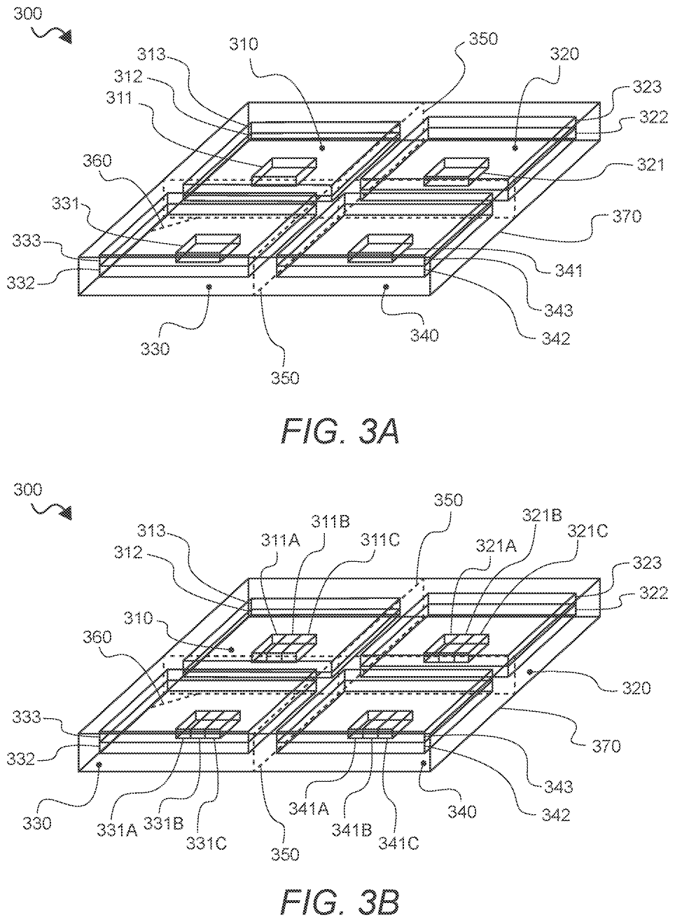

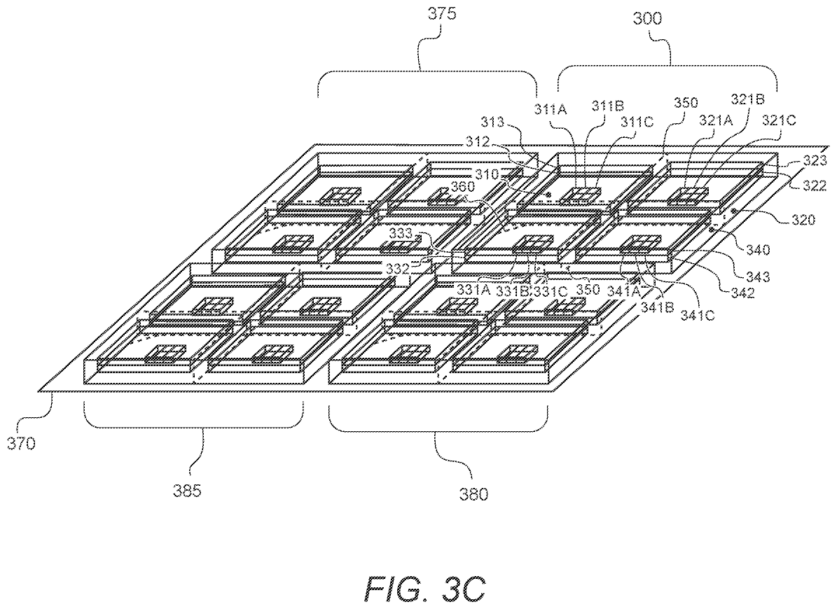

FIG. 3A illustrates a front perspective view of a multiple polarizing light emitting packages (MLEPs) assembly 300 mounted on a substrate 370. A light emitting element, polarizer, and diffuser are disposed in a sector within assembly 300, and the sectors are separated from each other via a separator wall 350. Sector 310 includes light emitting element 311, diffuser 312, and polarizing element 313. In the depicted embodiment, the diffuser 312 is disposed between the light emitting element 311 and the polarizer 313. Sector 320 includes light emitting element 321, diffuser 322, and polarizing element 323. Sector 330 includes light emitting element 331, diffuser 332, polarizing element 333, and a visually distinguishable feature 360. Sector 340 includes light emitting element 341, diffuser 342, and polarizing element 343. In a preferred embodiment, the separator wall 350 is positioned between the Sector 310 and the Sector 320. In a similar embodiment, the separator wall 350 is opaque to visible light. In a related embodiment, the separator wall 350 is disposed between polarizing element 313 and polarizing element 333. In some embodiments, a secondary separator wall (not shown) is positioned between the Sector 310 and the Sector 320. In a preferred embodiment, the separator wall 350 is configured to reduce cross-talk of polarized light between the sectors. In an embodiment, the polarizing elements are configured to be in contact with the separator wall 350. Advantageously, this configuration further insures no un-polarized light can escape the sectors or that only light that is transmitted from the sector of the MLEPs assembly 300 is polarized light.

The diffuser 312 is configured to be of substantially similar dimensions as that of the polarizing element 313 in order to diffuse the luminance emanated from light emitting element 311. Advantageously, this reduces the concentration of light on the polarizing element 313 and thus increases the efficiency of the polarizing element 313 by reducing the ghosting artifacts that interfere with the 3D effect. In some embodiments, the diffuser 312 is a material. In other embodiments, diffuser 312 is a solution. Moreover, the diffusion of light produced by the light emitting element 311 via diffuser 312 enhances the three-dimensional effect by 1) light spreading, creating a reduced lumens-per-square-millimeter value that enhances the polarization effect, and 2) point of light reduction, effectively smoothing the overall appearance of the display, thus making it possible to view the content on the display at a closer distance without apparent pixilation. In a depicted embodiment, the inclusion of the diffuser 140 spreads out the light from the light emitting element 311, which otherwise tends to “blow thru” polarizing element 313 causing a ghosting effect that may not be optimal for viewing.

FIG. 3B is similar to FIG. 3A, except with multiple light emitting elements disposed below the polarizing elements. Sector 310 includes light emitting element 311A, light emitting element 311B, and light emitting element 311C, where the light emitting elements 311A-311C are disposed below polarizing element 313. Sector 320 includes light emitting element 321A, light emitting element 321B, and light emitting element 321C, where the light emitting elements 321A-321C are disposed below polarizing element 323. Sector 330 includes light emitting element 331A, light emitting element 331B, and light emitting element 331C, where the light emitting elements 331A-331C are disposed below polarizing element 333. Sector 340 includes light emitting element 341A, light emitting element 341B, and light emitting element 341C, where the light emitting elements 341A-341C are disposed below polarizing element 343.

FIG. 3C illustrates a front perspective view of an alternative embodiment similar to FIG. 3B, with multiple polarizing light emitting packages (MLEPs) assemblies 300, 375, 380, and 385 mounted on a substrate 370.

In a preferred embodiment, diffuser 312 is configured to function as an anti-glare surface helping to reject ambient outdoor or room light from the glossy surface of the polarizing element 313. It is contemplated that the diffusion material serves for reducing glare from light emanated from light sources external to the display assembly. In some embodiments, diffuser 312 may be disposed in front of the custom cut shape of polarizing element 313, to reduce glare from light emanated from light sources outside the assembly 300. In some embodiments, an additional diffuser (not shown) is disposed on the exterior of the polarizing element, in addition to the diffuser 312 being between the light emitting element 311 and the polarizing element 313. Advantageously, this configuration would reduce point light and increase the polarization of the light produced by light emitting element 311. This also would reduce glare from the environment in which a display is situated, and would protect the surface of the polarizing element 313 from damage. In related embodiments, the diffuser 312 also increases the viewing angle of the display by projecting a polarized image of an illuminated pixel onto the front surface on the diffuser so as to be visible by a viewer at a wide angle.

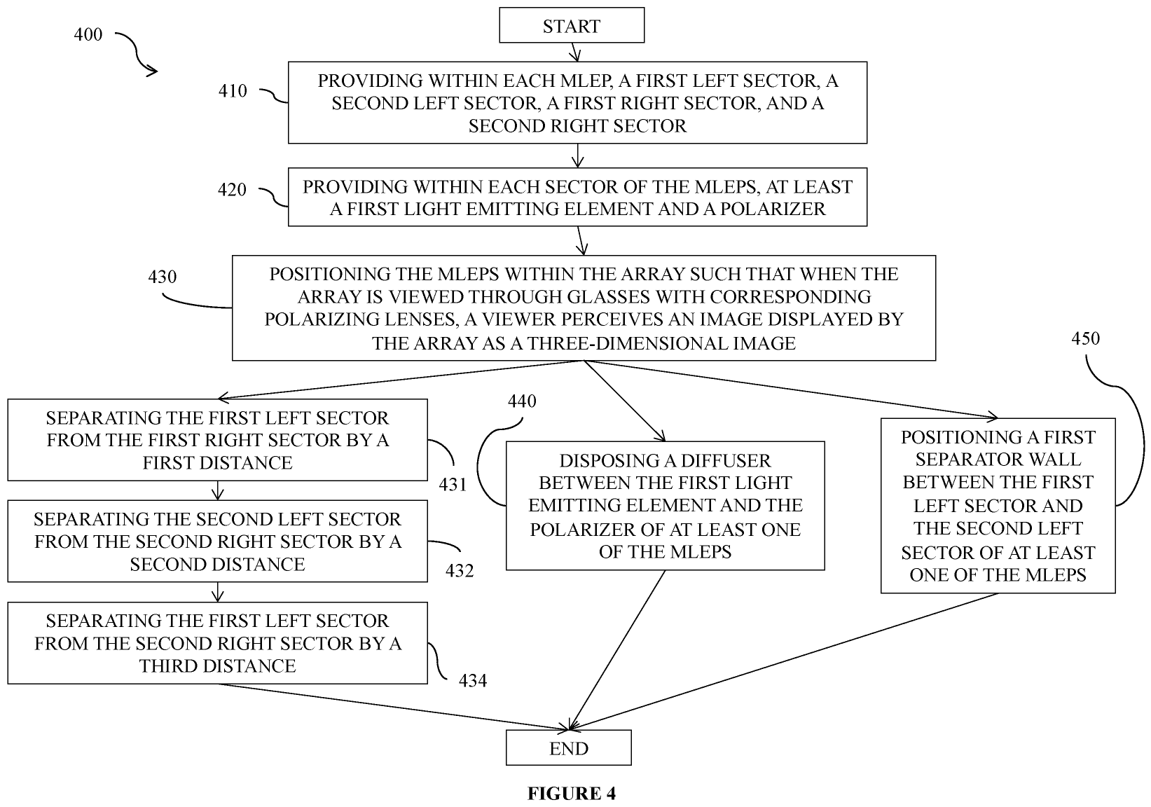

FIG. 4 is a functional block diagram illustrating the steps for method of manufacturing a stereoscopic display system having an array of multiple polarizing light emitting packages (MLEPs). FIG. 4 teaches providing within each of MLEPs, a first left sector, a second left sector, a first right sector, and a second right sector (step 410), providing within each sector of the MLEPs, at least a first light emitting element and a polarizer (step 420), and positioning the MLEPS within the array such that when the array is viewed through glasses with corresponding polarizing lenses, a viewer perceives an image displayed by the array as a three-dimensional image. (step 430).

The step of positioning the MLEPS within the array (step 430) further comprises separating the first left sector from the first right sector by a first distance (step 431) separating the second left sector from the second right sector by a second distance (step 432), and separating the first left sector from the second right sector by a third distance (step 433). In certain embodiments, the first distance is the same as the second distance. In related embodiments, the second distance is the same as the third distance. The combination of the precise orientation of the right polarizer(s) and left polarizer(s) assembled in an alternating pattern in a series of one LED module or multiple LED modules results in a 3D stereoscopic viewing experience when used with matched 3D glasses when images in a corresponding stereoscopic video format are transmitted. The corresponding 3D video format matches one or more left eye video pixel(s) with left polarized LEDs and one or more right eye video pixel(s) with right polarized LEDs, with all LEDs mounted on the circuit board/substrate. In a preferred embodiment, the light emitting elements within each MLEP are equidistant from the light emitting element in the adjacent MLEPs, when assembled on a LED module or LED display.

In the depicted embodiment, diffuser is disposed between the first light emitting element and the polarizer of at least one of the MLEPs (step 440), and the first separator wall is positioned between the first left sector and the second left sector of at least one of the MLEPs (step 450). In a preferred embodiment, the first separator wall is opaque to visible light. In a related embodiment, the first separator wall is disposed between the polarizer of the first left sector and the polarizer of the second left sector. In another preferred embodiment, a second separator wall is positioned between the first left sector and the first right sector.

In some embodiments, the first light emitting element is configured to emit a first color and a different second color. In a related embodiment, the first light emitting element is configured to additionally emit a third color different from the first and second colors. In another embodiment, each sector of the MLEPs further comprise a second light emitting element configured to emit at least one of the first color and the second color. It is further contemplated that at least 100 of the MLEPS can be arranged across at least 10 rows. In a similar embodiment, at least 100 of the MLEPS can be arranged across at least 10 diagonals. In a preferred embodiment, at least one of the MLEPs has a visually distinguishable feature selected from the group consisting of a key mark, a slot, and a cut-out.

It should be apparent to those skilled in the art that many more modifications besides those already described are possible without departing from the inventive concepts herein. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something designated from the group consisting of A, B, C . . . and N, the text should be interpreted as requiring only one element from the group, not A plus N, or B plus N, etc.

What is claimed is:

1. A stereoscopic display system, comprising:
an array of multiple polarizing light emitting packages (MLEPs), wherein:
each of MLEPs includes a first left sector, a second left sector, a first right sector, and a second right sector; and,
each sector of the MLEPs includes at least a first light emitting element and a polarizer; and,
the MLEPs are positioned and oriented within the array such that when the array is viewed through glasses with corresponding polarizing lenses, a viewer perceives an image displayed by the array as a three-dimensional image.

2. The stereoscopic display system of claim 1, wherein the first light emitting element is configured to emit a first color.

3. The stereoscopic display system of claim 2, wherein the first light emitting element is configured to emit a second color, different from the first color.

4. The stereoscopic display system of claim 3, wherein the first light emitting element is configured to additionally emit a third color different from the first and second colors.

5. The stereoscopic display system of claim 2, wherein each sector of the MLEPs further comprise a second light emitting element configured to emit at least one of the second color and the third color.

6. The stereoscopic display system of claim 1, wherein within each of the MLEPs of the array of multiple polarizing light emitting packages:
the first left sector is separated from the first right sector by a first distance;
the second left sector is separated from the second right sector by a second distance; and
the first left sector is separated from the second right sector by a third distance.

7. The stereoscopic display system of claim 6, wherein the first distance is the same as the second distance.

8. The stereoscopic display system of claim 6, wherein the second distance is the same as the third distance.

9. The stereoscopic display system of claim 1, wherein at least 100 of the MLEPs are arrange in the array across at least 10 rows.

10. The stereoscopic display system of claim 1, wherein at least 100 of the MLEPs are arrange in the array across at least 10 diagonals.

11. The stereoscopic display system of claim 1, wherein at least one of the MLEPs has a visually distinguishable feature selected from the group consisting of a key mark, a slot, and a cut-out.

12. The stereoscopic display system of claim 1, wherein at least one of the MLEPs comprises a diffuser disposed between the first light emitting element and the polarizer.

13. The stereoscopic display system of claim 1, wherein at least one of the MLEPs comprises a first separator wall positioned between the first left sector and the second left sector.

14. The stereoscopic display system of claim 13, wherein the first separator wall is opaque to visible light.

15. The stereoscopic display system of claim 13, wherein the first separator wall is disposed between the polarizer of the first left sector and the polarizer of the second left sector.

16. The stereoscopic display system of claim 13, further comprising a second separator wall positioned between the first left sector and the first right sector.

17. A method of manufacturing a stereoscopic display system having an array of multiple polarizing light emitting packages (MLEPs),
providing within each of MLEPs, a first left sector, a second left sector, a first right sector, and a second right sector;
providing within each sector of the MLEPs, at least a first light emitting element and a polarizer; and,
positioning the MLEPs within the array such that when the array is viewed through glasses with corresponding polarizing lenses, a viewer perceives an image displayed by the array as a three-dimensional image.

18. The method of claim 17, wherein the first light emitting element is configured to emit a first color.

19. The method of claim 18, wherein the first light emitting element is configured to emit a second color, different from the first color.

20. The method of claim 19, wherein the first light emitting element is configured to additionally emit a third color different from the first and second colors.

21. The method of claim 19, wherein each sector of the MLEPs further comprise a second light emitting element configured to emit at least one of the first color and the second color.

22. The method of claim 17, further comprising, in at least one of the MLEPs:
separating the first left sector from the first right sector by a first distance;
separating the second left sector from the second right sector by a second distance; and,
separating the first left sector from the second right sector by a third distance.

23. The method of claim 22, wherein the first distance is the same as the second distance.

24. The stereoscopic display system of claim 22, wherein the second distance is the same as the third distance.

25. The method of claim 17, further comprising arranging at least 100 of the MLEPS across at least 10 rows.

26. The method of claim 17 further comprising arranging at least 100 of the MLEPS across at least 10 diagonals.

27. The method of claim 17, wherein at least one of the MLEPs has a visually distinguishable feature selected from the group consisting of a key mark, a slot, and a cut-out.

28. The method of claim 17, further comprising disposing a diffuser between the first light emitting element and the polarizer of at least one of the MLEPs.

29. The method of claim 17, further comprising positioning a first separator wall between the first left sector and the second left sector of at least one of the MLEPs.

30. The method of claim 29, wherein the first separator wall is opaque to visible light.

31. The method of claim 29, wherein the first separator wall is disposed between the polarizer of the first left sector and the polarizer of the second left sector.

32. The method of claim 29, further comprising positioning a second separator wall between the first left sector and the first right sector.
